(19) United States
(12) Patent Application Publication
(10) Pub. No.: US 2023/0235664 A1
(43) Pub. Date: Jul. 27, 2023

(54) ENVIRONMENTAL SYSTEM-IN-PACKAGE FOR HARSH ENVIRONMENTS

(71) Applicant: Schlumberger Technology Corporation, Sugar Land, TX (US)

(72) Inventors: Remi Robutel, Clamart (FR); Cleverson Souza Chaves, Clamart (FR); Mohamed Salim Cherchali, Clamart (FR); Claire Tassin, Clamart (FR); Nicolas Renoux, Clamart (FR)

(21) Appl. No.: 17/582,816

(22) Filed: Jan. 24, 2022

(51) Int. Cl. E21B 47/07; B81B 7/00; E21B 47/12; E21B 47/01

(52) U.S. Cl. CPC E21B 47/07; B81B 7/0074; E21B 47/01; E21B 47/12; B81B 2201/025; B81B 2201/0214; B81B 2201/0235; B81B 2201/0242; B81B 2201/0264; B81B 2201/0278; B81B 2201/0292; B81B 2207/07; B81B 2207/091

(57) ABSTRACT

A downhole sensor system includes a first sensor package having a substrate, an integrated circuit chip mounted to the substrate, the integrated circuit chip including a processor, a transducer chip mounted to the integrated circuit chip, and a plurality of sensors configured to measure at least shock, pressure, temperature, and humidity. At least one of the plurality of sensors is mounted to the transducer chip such that a stack is formed at least from the substrate, the integrated circuit, the transducer chip, and the sensor. The plurality of sensors are in communication with the processor.

### BACKGROUND

In the oilfield, monitoring of downhole conditions is employed to detect and/or anticipate issues related to drilling, completion, and/or production. For example, equipment health management processes detect and/or anticipate issues with various downhole devices. Equipment health management may provide enhanced fleet management, improved Cost of Service Delivery (CoSD), Total Cost of Ownership (TCO), Asset utilization, and Failures and Capex optimization (less Capex, better forecast).

When a large amount of data is collected or a well-known physics is applicable, prognostics through analytics may be implemented. This is referred to as Prognostic Health Management (PHM). From basic diagnostics to advanced PHM, monitoring and decision-making rely on robust information acquisition. When possible, sensors are used to correlate between maintenance indicators/triggers and the physics of failure.

For downhole equipment, for example, failures may stem from shocks and vibrations, which may cause mechanical damage to multiple parts like electronics, seals, connectors, and other structures. Degradation may be accelerated by an elevated operating temperature, usually above 125° C. Another source of failure may be moisture trapping and leakage from the environment, e.g., in electronic components. Moreover, the combined effects of these conditions (e.g., elevated moisture content and temperature together) can dramatically reduce the life of a device.

However, data acquisition in a downhole environment, so as to detect these conditions, presents a challenge. The conditions in the wellbore are especially harsh. Sensors used in a device that is deployed into a wellbore generally contend with high temperatures, pressures, and shock, and vibration. Moreover, communication with these sensors may be constrained to relatively low bandwidth, e.g., with mud pulse telemetry. Sensors have been developed to measure the conditions, individually, in a ruggedized construction; however, these sensors are expensive and thus, for example, generally call for calibration individually, further increasing the expenses associated therewith.

### SUMMARY

Embodiments of the disclosure include a downhole sensor system that includes a first sensor package having a substrate, an integrated circuit chip mounted to the substrate, the integrated circuit chip including a processor, a transducer chip mounted to the integrated circuit chip, and a plurality of sensors configured to measure at least shock, pressure, temperature, and humidity. At least one of the plurality of sensors is mounted to the transducer chip such that a stack is formed at least from the substrate, the integrated circuit, the transducer chip, and the sensor. The plurality of sensors are in communication with the processor.

Embodiments of the disclosure also include a method for measuring downhole conditions. The method includes connecting a first sensor package to a first downhole device, the first sensor package having a first sensor package including a substrate, an integrated circuit chip mounted to the substrate, the integrated circuit chip including a processor, a transducer chip mounted to the integrated circuit chip, and a plurality of sensors configured to measure at least shock, pressure, temperature, and humidity. At least one of the plurality of sensors is mounted to the transducer chip such that a stack is formed at least from the substrate, the integrated circuit, the transducer chip, and the sensor. The plurality of sensors are in communication with the processor. The method also includes measuring conditions using the first sensor package, and communicating the conditions from the first sensor package to a processing system using the processor of the first sensor package.

Embodiments of the disclosure further include a sensor package including a substrate, an integrated circuit chip mounted to the substrate, the integrated circuit chip including a processor, a transducer chip mounted to the integrated circuit chip, and a plurality of sensors configured to measure at least shock, pressure, temperature, and humidity. At least one of the plurality of sensors is mounted to the transducer chip such that a stack is formed at least from the substrate, the integrated circuit, the transducer chip, and the sensor. The sensors are in communication with the processor. The sensors include micro-electromechanical system (MEMS) devices, and are configured to measure a temperature range of -55 C to 200 C, relatively humidity of at least 10%, and shock of up to 10,000 g.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates a schematic view of a wellsite system, according to an embodiment.

FIG. 2 illustrates a perspective view of a sensor package, according to an embodiment.

FIG. 3 illustrates a functional block diagram of the sensor package, according to an embodiment.

FIG. 4 illustrates a simplified perspective view of part of the sensor package, according to an embodiment.

FIG. 5 illustrates another simplified perspective view of part of the sensor package, according to an embodiment.

FIG. 6 illustrates an example of ball grid array interconnects, according to an embodiment.

FIG. 7 illustrates a simplified perspective view of the sensor package, including a printed circuit board (PCB), to which the substrate is mounted, and a clamp for connecting the PCB to a chassis, according to an embodiment.

FIG. 8 illustrates a top view of the PCB and the clamp, according to an embodiment.

FIG. 9 illustrates an example of a stack of chips for use in the sensor package, according to an embodiment.

FIG. 10 illustrates another embodiment of the sensor package, which may include a flip-chip construction.

FIG. 11 illustrates a conceptual view of a wellsite system that employs a network 1100 of sensor packages, according to an embodiment.

FIG. 12 illustrates a flowchart of a method for measuring downhole conditions at a wellsite, according to an embodiment.

FIG. 13 illustrates a schematic view of a computing system, according to an embodiment.

### DESCRIPTION OF EMBODIMENTS

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object could be termed a second object, and, similarly, a second object could be termed a first object, without departing from the scope of the invention. The first object and the second object are both objects, respectively, but they are not to be considered the same object.

The terminology used in the description of the invention herein is for the purpose of describing particular embodiments only and is not intended to be limiting of the invention. As used in the description of the invention and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

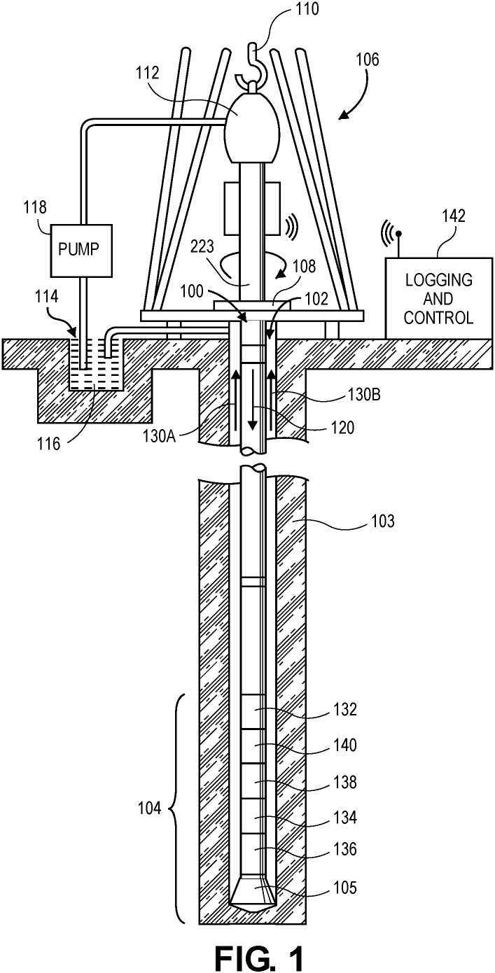

FIG. 1 illustrates a wellsite system according to examples of the present disclosure may be used. The wellsite can be onshore or offshore. In this example system, a drill string 100 is suspended in a borehole 102 formed in subsurface formations 103. The drill string 100 has a bottom hole assembly (BHA) 104 which includes a drill bit 105 at its lower end. A surface system 106 includes platform and derrick assembly positioned over the borehole 102, the assembly including a rotary table 108, kelly (not shown), hook 110, and rotary swivel 112. The drill string 100 is rotated by the rotary table 108 energized by a driver, which engages the kelly (not shown) at the upper end of the drill string 100. The drill string 100 is suspended from the hook 110, attached to a traveling block (also not shown), through the kelly (not shown) and the rotary swivel 112 which permits rotation of the drill string 100 relative to the hook 110. A top drive system could be used instead of the rotary table system shown in FIG. 1.

In the illustrated example, the surface system 106 further includes drilling fluid or mud 114 stored in a pit 116 formed at the well site. A pump 118 delivers the drilling fluid to the interior of the drill string 100 via a port (not shown) in the swivel 112, causing the drilling fluid to flow downwardly through the drill string 100 as indicated by the directional arrow 120. The drilling fluid exits the drill string 100 via ports (not shown) in the drill bit 105, and then circulates upwardly through an annulus region between the outside of the drill string 100 and the wall of the borehole 102, as indicated by the directional arrows 130A and 130B. In this manner, the drilling fluid lubricates the drill bit 105 and carries formation cuttings up to the surface as it is returned to the pit 116 for recirculation.

The BHA 104 of the illustrated embodiment may include a measuring-while-drilling (MWD) tool 132, a logging-while-drilling (LWD) tool 134, a rotary steerable directional drilling system 136 and motor, and the drill bit 105. It will also be understood that more than one LWD tool and/or MWD tool can be employed, e.g., as represented at 138.

The LWD tool 134 is housed in a drill collar and can contain one or a plurality of logging tools. The LWD tool 134 may include capabilities for measuring, processing, and storing information, as well as for communicating with the surface equipment. In the present example, the LWD tool 134 may include one or more tools configured to measure, without limitation, electrical resistivity, acoustic velocity or slowness, neutron porosity, gamma-gamma density, neutron activation spectroscopy, nuclear magnetic resonance and natural gamma emission spectroscopy.

The MWD tool 132 is also housed in a drill collar and can contain one or more devices for measuring characteristics of the drill string and drill bit. The MWD tool 132 further includes an apparatus 140 for generating electrical power for the downhole system. This may typically include a mud turbine generator powered by the flow of the drilling fluid, it being understood that other power and/or battery systems may be employed. In the present embodiment, the MWD tool 132 may include one or more of the following types of measuring devices, without limitation: a weight-on-bit measuring device, a torque measuring device, a vibration measuring device, a shock measuring device, a stick slip measuring device, a direction measuring device, and an inclination measuring device. The power generating apparatus 140 may also include a drilling fluid flow modulator for communicating measurement and/or tool condition signals to the surface for detection and interpretation by a logging and control unit 142.

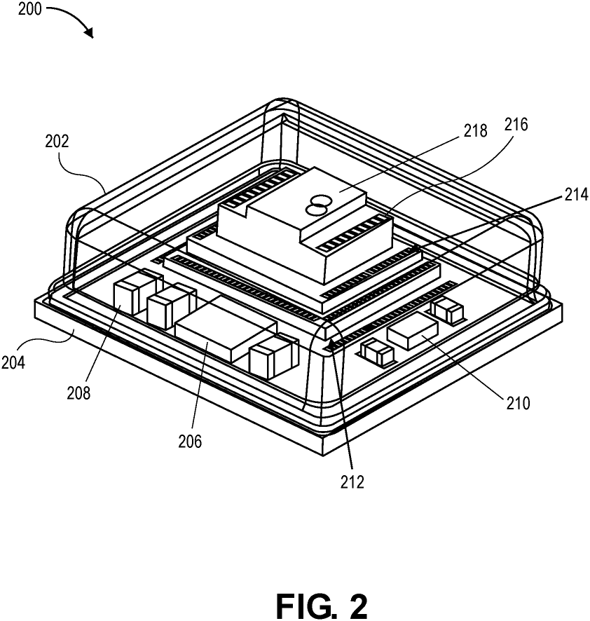

FIG. 2 illustrates a perspective view of a sensor package 200, according to an embodiment. The sensor package 200 includes a cover 202, which is illustrated as transparent to permit viewing of the interior of the sensor package 200, but may be opaque or translucent in practice. The sensor package 200 generally includes a substrate 204. In some embodiments, the cover 202 may be configured to expose internal components therein to the environment, so as to permit measurements to be taken accurately. In other embodiments, at least a portion of the interior of the cover 202 may be hermetically sealed, e.g., sealed to the substrate 204, and may be filled with nitrogen or argon, for example.

One or more sensors 206 may be mounted to the substrate 204. Further, one or more passive components 208 (e.g., for decoupling capacitors, pull-up resistors, pull-down resistors, voltage dividers, passive analog filters, high-frequency filters and miniature antennas) and one or more active components (e.g., resonators) 210 may also be mounted to the substrate 204.

The sensor package 200 may further include a system-in-package design, including a plurality of micro-electro-mechanical system (MEMS) devices, e.g., “stacked” vertically (in a direction normal to the plane of the various chips) which may be or include miniaturized digital sensors. For example, the sensor package 200 may include an integrated circuit (IC) chip (or “IC board” or “IC chip”) 212 mounted to the substrate 204. A microprocessor may be integrated in the IC 212. The microprocessor may communicate with the sensor(s) 206, the passives 208, and/or the resonator 210 via conductive paths in the substrate 204. A stack of one or more chips may be mounted to the IC 212. For example, the stack may include an application specific integrated chip (ASIC) 214 that is mounted to the IC 212. One or more transducer chips 216 may be mounted to the ASIC 214 (e.g., part of the IC stack), and may include or be connected to one or more transducers (sensors) 218. The sensors 218 may be MEMS devices.

The sensor 206 may be configured, in at least one example, to measure relative humidity, e.g., within the sensor package 200 or external thereto. The relative humidity measurement may provide conditions information for the health of the device. The sensor package 200 may be configured to operate in conditions ranging from 0% to 100% relative humidity, e.g., at least about 5% humidity and/or up to about 90% relative humidity. In at least some embodiments, the sensor 206 may be configured to trigger maintenance events or raise flags when detecting 10-20% humidity.

The sensors 218 may be configured to measure temperature, pressure, and/or shock. For example, the sensors 218 may be configured to measure temperatures ranging from -55° C. to 200° C. For example, the sensor package 200 may be operable at high temperatures in excess of 125° C. Further, the sensors 218 may be configured to measure pressures ranging from 10 mbar to 2000 bar, e.g., with at least some of the sensors 218 immersed in a fluid such as hydraulic oil. For example, the sensor package 200 may be configured to operate in downhole environments of between about 10 mbar to about 10 bar, absolute pressure. The sensors 218 may be configured to measure shock above 1000 g and up to 10,000 g. For example, the sensors 218 may measure up to 1000 g at high rates, such as 10 Hz, and up to 10,000 g. Further, the sensors 218 may be configured to measure vibrations levels above 50gRMS.

The physical principles used for the sensors 206, 218 may be compatible with MEMS processing capabilities on four-inch, six-inch, or eight-inch semiconductor wafers made of silicon. For shocks, in-plane and out-of-plane proof-of-mass may be used to collect kinetic energy. Further, shock sensing physical principles may be or include electrostatic/capacitive, piezoelectric, or piezoresistive. For pressure, air or vacuum sealed cavity by wafer bonding techniques may be used to provide an absolute pressure measurement. For pressure, sensing physical principle could be electrostatic/capacitive, piezoelectric or piezoresistive. For temperature, a conductive or a semiconductor material could be used such as the platinum or doped silicon or another semiconductor material such as silicon carbide or gallium nitride or diamond. Temperature transducer could have multiple sensing elements. The humidity transducer may use a resistive structure or a capacitive structure for which a specific thin-film provides selectivity and sensibility to H₂O absorption and desorption. The specific thin-film for humidity transducer may be an organic material such as a polymer. In each of the transducers, resonant structures may be used to sense a physical measurement versus the change of single or multi-modes resonant frequencies.

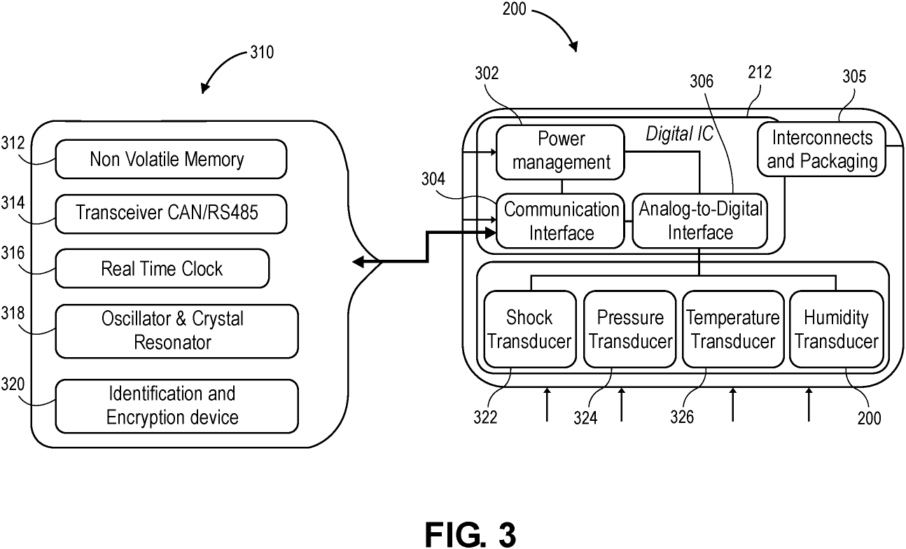

FIG. 3 illustrates a functional block diagram of the sensor package 200, according to an embodiment. As shown, the IC 212 includes a power management module 302 and a communications interface/module 304. These two modules 302, 304 may permit the sensor package 200 to be at least partially autonomous, in that the sensor package 200 can run on its own power (e.g., by connection with an on-board power source) and communicate with external devices (e.g., via a communications port, whether wired or wireless), e.g., a centralized processor as part of a network of sensor packages 200, as will be described in greater detail below.

The sensor package 200 may also include an interconnect and packaging module 305, which may connect the IC 212 to the substrate 204 and/or other components on a printed circuit board (PCB), as will be described below. The IC 212 may be representative of a single IC or several ICS that are coupled together. For the sake of simplicity, the IC 212 will be described with respect to FIG. 3 in the singular, but it will be appreciated that the functions may be distributed among several ICs (e.g., ASICs, etc.). The IC 212 supplies, manages, and senses signals from the sensors 206, 218. The IC 212 may be tailored to electrical characteristics of the sensors 206, 218 such as the supply voltage(s), signal frequencies, signal levels, open or closed loop sensing methods, physical positioning of pads, matching impedances, and/or interconnect impedance.

The IC 212 may further include an analog-to-digital converter 306, which may be configured to convert analog signals from the sensors 206, 218 to digital signals that can be processed by the processor, e.g., for analysis, transmission, etc. The IC 212 manages analog signals as an Analog-Front End (AFE) circuit. It performs also the Analog-to-Digital Conversion (ADC), e.g., using a Successive Approximation Register (SAR) ADC or Sigma-Delta ADC with signal-to-noise ratio equal or better than 60 dB, and bandwidth ranging from 0.5 Hz to 50 kHz. The Analog-to-Digital Interface may be a single chip or the combination of multiple chips. Beyond the signal conditioning and the ADC functions, the Analog-to-Digital Interface may provide additional functions such as buffer memories, task manager and a communication port like a I2C or SPI or CAN communication link.

The IC 212 may also include a processing unit used to configure and manage measurement data from an Analog-to-Digital Interface to an external controller. The processing unit may be a 32 bits fixed-point processor or a 32 bits floating-point processor. The processing unit may have non-volatile and volatile memories to process the measurement data. The processing unit may have a communication module to communicate with an external controller that is able to handle a CAN protocol and/or a SPI protocol and/or a I2C protocol and/or a RS232 protocol. The IC 212 including the processing unit may have processing capabilities from 10 MIPS to 100 MIPS (Million Instruction Per Second). The processing unit may be able to run an embedded operating system. The IC 212 may have integrated passive devices, as noted above.

The IC 212 functions may be integrated into a single chip or into multiple chips depending on functions and electronics technology which is used. Different physical configuration may be implemented like a single chip or collocated chips or stacked chips. The IC 212 may have typical dimensions ranging from 100 µm to 2 mm in thickness, from 500 µm to 10 mm in length, from 500 µm to 10 mm in width.

The IC 212 may also communicate with one or more peripheral devices 310, which may be external to the sensor package 200. For example, such peripheral devices 310 may include non-volatile memory 312, to which the sensor package 200 is able to read from and write to. Such external memory may be a NAND flash or nor flash memory chip connected to a dedicated peripheral SPI link. The protocol is defined and managed by the peripheral driver.

Another peripheral device 310 may be a transceiver 314, which permits the sensor package 200 to communicate with an interface (e.g., a CAN bus or serial bus link) using an external transceiver. In an example, an embedded CAN module may be provided within the IC 212, which couples with a CAN transceiver at speed of 1 Mbps. The protocol may be a standardized CAN protocol or a customized CAN protocol.

The peripheral devices 310 may also include a Real Time Clock (RTC) 316. The sensor package 200 may be able to operate the RTC to minimize power consumption. For example, the sensor package 200 may enter a sleep mode with very low power consumption. In this mode, the RTC may count time and maintain the time reference. From an external event, the “combo-sensor” wakes up and can recover the time reference from the external RTC.

The peripheral devices 310 may further include an oscillator and crystal resonator 318. The sensor package 200 may be able to use an external clock source from an oscillator or from a crystal resonator (e.g., active component 210 of FIG. 2), which may facilitate operations in harsh environments and tight requirements in frequency stability over temperature ranges. Therefore, the IC 212 may not meet such requirements and thus may access such an external clock. An example configuration is a high-temperature, high reliability quartz-based oscillator, in the range of 100 ppm to 500 ppm over the full operating temperature range.

Further, the sensor package 200 may be coupled to a unique ID and encryption key generators 320 by using external Trusted Platform Module (TPM). Such TPM may run a cryptographic algorithm to generate an authentication key, e.g., based on the Trusted Computing Group (TCG) Trusted Platform Module Library specifications. This may enable the protection of the data or the use of some information measured or recorded by the sensor package 200.

The sensors 218, as mentioned above, may include a shock transducer 322, a pressure transducer 324, and a temperature transducer 326. These may be MEMS sensors, with the operating ranges discussed above. Further, the sensor 206 may be or include a humidity sensor. Various other sensors may be included in the sensor package 200, such as a volatile organic compound (VOC) sensor (e.g., to detect ethane, carbon monoxide, ethanol, butadiene, isoprene, acetone), and/or one or more inertial sensors, such as gyroscopes, accelerometers, and/or magnetometers. The transducers 322, 324, 326 may be designed as MEMS using silicon technology, or could be integrated with regular integrated circuit designs using CMOS technologies and thin-film processes. The transducers 322, 324, 326 may be discrete silicon chips or plastic or ceramic package of components. In an embodiment, the transducers 322, 324, 326 may be a bare die (a silicon chip) or Wafer Level Chip Scale Package (WLCSP). Two or more of the transducers 322, 324, 326 may be integrated in a single silicon chip. Further, the transducers 322, 324, 326 may be made of another semiconductor material such as silicon carbide or gallium nitride or diamond. The transducers 322, 324, 326 may have dimensions ranging from 100 µm to 2 mm in thickness, from 500 µm to 5 mm in length, from 500 µm to 5 mm in width.

Industrial systems and embedded systems manage multiple functions and subsystems. An architecture is defined for power supply and communication links between the multiple subsystems and parts. Modern digitalized embedded systems have significant processing capabilities, and high bandwidth, short delay communication links. Therefore, they can handle large number of sensors and peripherals for real-time control and operation of the system, and also for health monitoring of the system (or the equipment). This may permit access to synchronized multi-channel measurements, which in turn may permit advanced process control and real-time analysis. Such capabilities may employ a complex fusion algorithm and/or feed global multiphysics models. Finally, real-time decision, alerts, monitoring or process control may be implemented using such processing and communication capabilities.

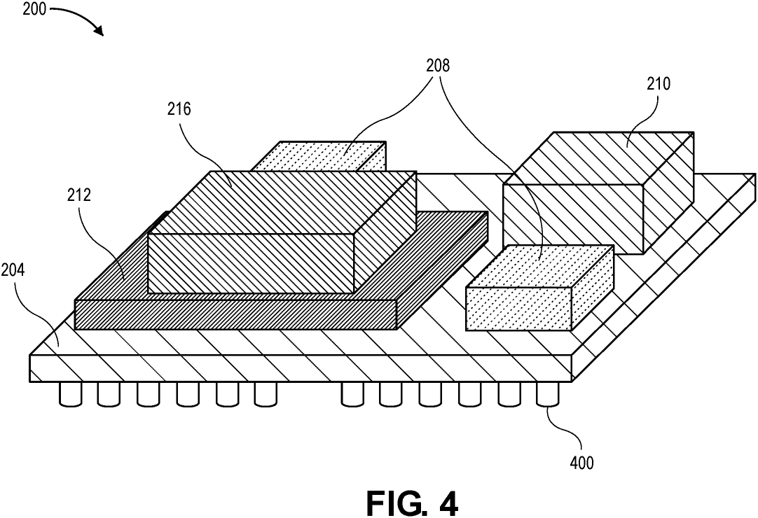

FIG. 4 illustrates a simplified perspective view of part of the sensor package 200, according to an embodiment. In particular, the substrate 204 is illustrated, with the IC 212 and the transducer chips 216 mounted or “stacked” thereto. As also shown, the passive and/or active components 208, 210 may be mounted to the substrate 204. The substrate 204 in turn may include or have extend therefrom electrical contacts 400, which may provide connectivity to a mother board (e.g., a printed circuit board (PCB)), so as to provide connection and/or electrical connectivity with other elements connected to the PCB.

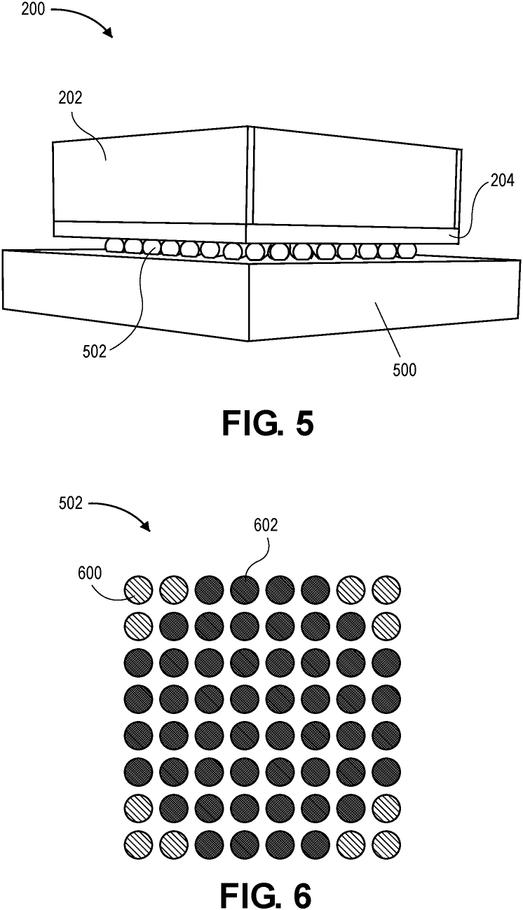

FIG. 5 illustrates another simplified perspective view of part of the sensor package 200, according to an embodiment. In this view, the cover 202 has been adhered or otherwise attached to the substrate 204, covering (e.g., sealing) the components therein. Further, as shown, the substrate 204 is coupled to a printed circuit board (PCB) 500. The connection between the substrate 204 and the PCB 500 may be specifically configured to survive high-g shocks and vibrations, and avoid decoupling due to thermal expansion (and/or differences in coefficients of thermal expansion between the various components), such as those discussed above. For example, the substrate 204 may be mechanically attached with a distributed strength to the PCB 500. Pin Grid Array (PGA) and a Ball Grid Array (BGA), as indicated generally by reference number 502, may be used to provide distribution of attachment strength.

FIG. 6 illustrates an example of the connection of the BGA 502 interconnects, according to an embodiment. The solder balls are the solder joints of the BGA after the reflow soldering process is performed. The soldering may be conducted using a tin-based alloy or with straight pins made of invar, covar, copper, gold or lead. In particular, the connections may be avoided at the corners in positions 600, with positions 602 making the connections. For high temperature applications, the size of the substrate 204 may not exceed a length of 10 mm and a width of 10 mm because of CTE mismatch and liquidus temperature interconnects from regular electronics mounting methods. In other embodiments, a land grid array may be implemented to connect the substrate 204 and the PCB 500. In such an embodiment, a solder paste may be employed to solder the substrate 204 directly on the PCB 500. In still other embodiments, any combination of connection types described herein, or others, may be employed.

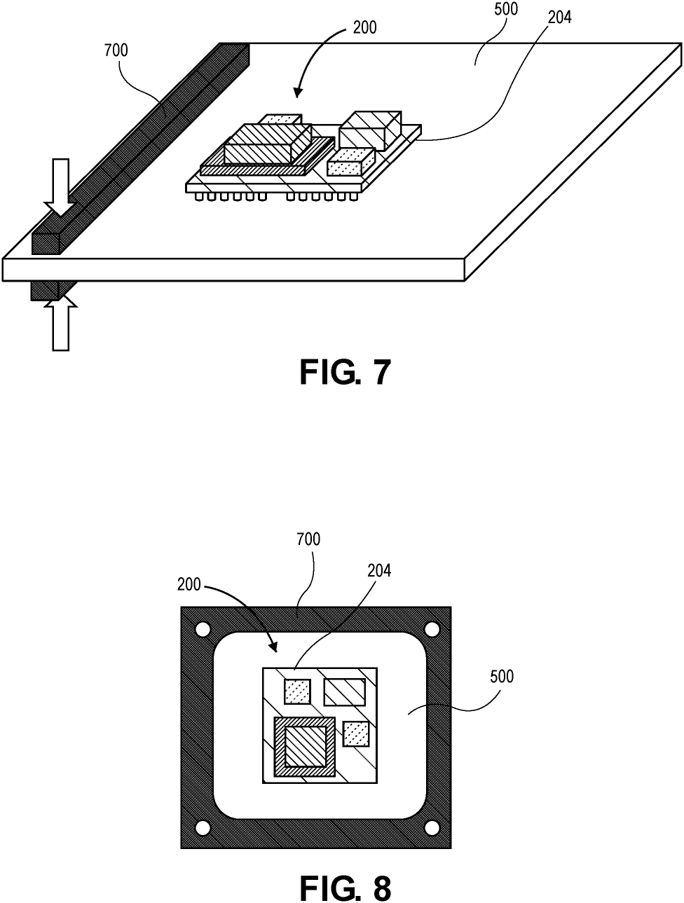

FIG. 7 illustrates a simplified perspective view of the sensor package 200 including the PCB 500, to which the substrate 204 is mounted, and a clamp 700 for connecting the PCB 500 to a chassis. As illustrated, the clamp 700 may be formed from a pair of linear members that are mounted to either side of the PCB 500 and, e.g., pressed together, by a clamping force. The substrate 211 may be mounted to the PCB 500 proximal to the clamp 700, so as to avoid the PCB 500 resonating during use in the presence of the shock and vibration discussed above.

In particular, the PCB 500 with the clamp 700 may be designed to produce a transmissibility in the PCB 500 of approximately 1. For example, the clamp force applied by the clamp 700 to connect the PCB 500 to the chassis may be from about 3 MPa to about 50 MPa, depending on the substrate material. This construction may provide a high stiffness to the assembly of the sensor package 200 on the PCB 500, and the PCB 500 on the chassis. The clamp 700 may be made of stainless-steel alloys, aluminum alloys, or titanium alloys depending on application requirements.

FIG. 8 illustrates a top view of the PCB 500 and the clamp 700, according to an embodiment. In this embodiment, the clamp 700 extends along the periphery of the PCB 500, thereby surrounding the sensor package 200. In at least some embodiments, the assembly illustrated in FIG. 8, e.g., the PCB 500 and the clamp 700 may have a length from 15 mm to 100 mm and a width from 15 mm to 100 mm.

Maintaining the transmissibility at or approximately (within 10% of) 1 may avoid the resonant frequency of the PCB 500 being within the measurement bandwidth of the shocks and vibrations expected in the downhole environment. For example, the resonant frequency may be maintained above a first mechanical resonant mode of 5 kHz. Transmissibility is calculated as follows.

$$T = \left|\frac{{A}_{n}}{{A}_{t}}\right| = \sqrt{\frac{1 + {\left(2 ζ \frac{{f}_{d}}{{f}_{n}}\right)}^{2}}{{\left[1 - {\left(\frac{{f}_{d}}{{f}_{n}}\right)}^{2}\right]}^{2} + {\left[2 ζ \frac{{f}_{d}}{{f}_{n}}\right]}^{2}}}$$

where A₀is the amplitude of the vibration response, Aᵢis the amplitude of vibrational input, ζ is the damping ration, ƒ_{d}is the driving frequency, and ƒₙis the natural frequency. Modal analysis from calculations and simulations may be performed to configure the assembly of 200 onto 500. Further, operating conditions, such as a transmissibility of 1, may be verified.

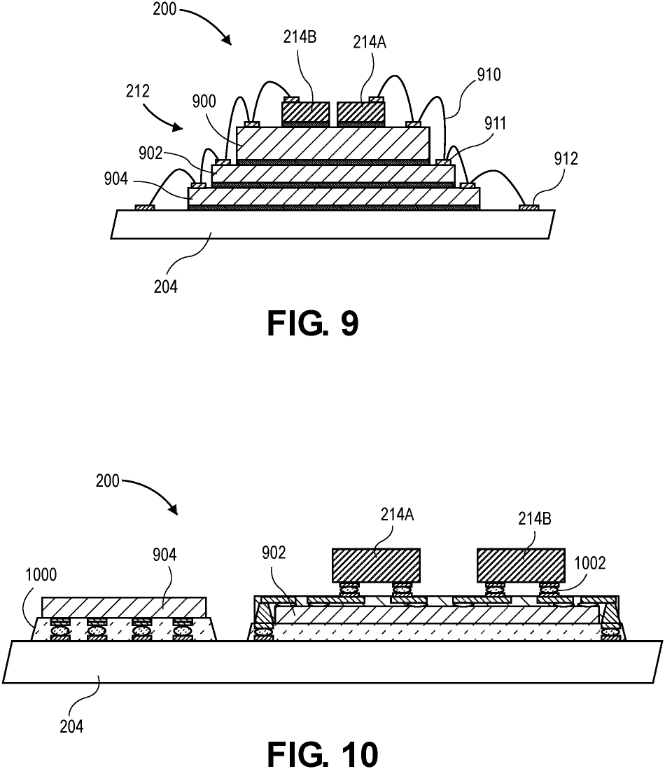

FIG. 9 illustrates an example of a stack of chips for use in the sensor package 200, according to an embodiment. In particular, this stack of chips reflects a “system in package” (SIP) design. Further, the stack includes the substrate 204, the IC 212, and the transducer chips (two shown: 214A, 214B). In this embodiment, the IC 212 is made up of three integrated circuit chips 900, 902, 904, which are stacked vertically on one another and connected to the substrate 204.

In at least some embodiments, the materials, integrations, and interconnections are configured to withstand harsh conditions. The miniaturization envisioned by the SIP through die integration may lead to smaller solder joints (micro-bumps) that may be less reliable compared to individual package components, that can still be worsened by coefficient of thermal expansion (CTE) material mismatches. Accordingly, in at least some embodiments, different options for construction may be available. For example, micro-bumps with under bump metallization of Ti/TiW adhesion layers plus electrodeposited layers (gold or solder) may be used in some embodiments for interconnections done through aluminum wire bonds and gluing on electroless nickel, electroless palladium, immersion gold (ENEPIG) substrate bond pads in others. These interconnections may be used in combination soldered connections, as the substrate 204 material may have a high Tg combined with low CTE due the nature of fillers and resin used in its fabrication, as discussed in greater detail below.

Considering the embodiment of FIG. 9 in greater detail, the stack uses each layer (e.g., chip or other component) as the basis for the next one. Further, each layer may include a die pad 911, which permits a wire 910 to connect the different layers 900-904 and 214A, 214B together. The different layers may be glued and wire bonded. Further, the substrate 204 may include a metallization 912 for connection to the wire 910.

In this embodiment, a low CTE organic substrate may be employed. The substrate resin may be polyimide based, filled with ceramic and/or glass particles, to withstand elevated temperatures. By reducing the CTE, the stresses applied on the stack may be decreased. Moreover, organic substrates may improve production scalability and decrease cost. Further, the substrate metallization may be ENEPIG so as to be compatible with soldering and wire bonding. This may improve production yield. Further, the nickel barrier may decrease intermetallic growth under elevated temperatures, which may increase the robustness of the sensor package 200. Further, the wire 910 may be aluminum to be compatible with aluminum die pad metallization. The substrate 204 may include gold, but may be a thin layer, so as to mitigate issues with aluminum/gold intermetallic under elevated temperature.

FIG. 10 illustrates another embodiment of the sensor package 200, which may include a flip-chip construction. In this embodiment, the stack of ICs 212 may include the first and second ICs 900, 902, which may be connected to the substrate 204 via one or more interconnections routed through a flip-chip 1000. The flip-chip 1000 may include one or more micro-bumps 1002 for physical and electrical interconnection with the sensors 218. The bump 1002 in the flip-chip could be formed by gold stud bumping or microsoldering. Further, in some embodiments, one or more of the ICs 212 may be connected via wire bonding interconnection (as in FIG. 9) and one or more of the ICs 212 may be connected using flip-chip interconnection (FIG. 10), so as to combine the embodiments of FIGS. 9 and 10.

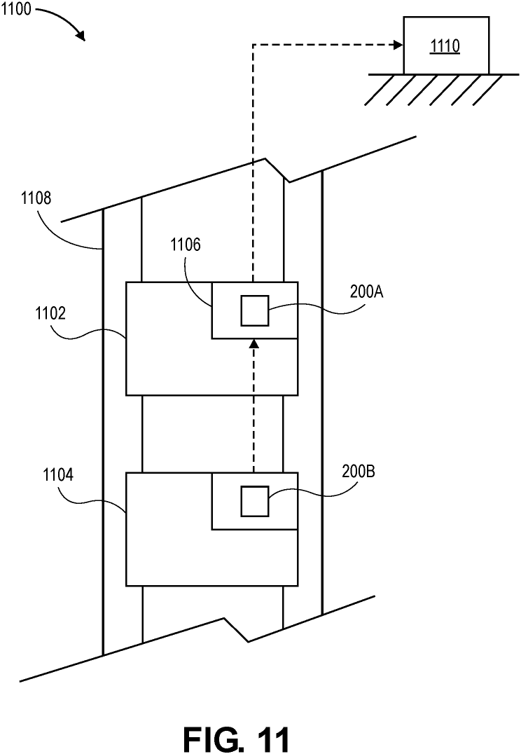

FIG. 11 illustrates a conceptual view of a wellsite system that employs a network 1100 of sensor packages (e.g., 200A, 200B), according to an embodiment. In particular, the wellsite system may include several downhole devices 1102, 1104 that may be monitored for health. Accordingly, the sensor packages 200A, 200B may be connected thereto (e.g., via a chassis 1106). The sensor packages 200A, 200B may thus be deployed into a wellbore 1108 along with the devices 1102, 1104, and may measure conditions therein. The sensor packages 200A, 200B may be configured to transmit data to and/or from each other, and/or to/from a central processing device 1110.

The central processing device 1110 may be located at the surface of the wellsite, e.g., on site or remote from the top of the wellbore 1108. In some embodiments, the sensor packages 200A, 200B may transmit digital data signals representing raw measurements taken by the sensors 206, 218 therein (e.g., FIG. 2), processed signals (e.g., Fast Fourier Transform, wavelet transform, Hilbert transform), signal features such as peak values, frequency detection, event occurrences, threshold detections, intercorrelation techniques, multiple transforms, filtering/detection techniques, etc. Furthermore, machine learning algorithms are also deployed, e.g., as part of an Internet-of-Things (IoT) embodiment of the network 1100. Such an implementation may employ measurements which are transferred to a server (e.g., the central processing device 1110) that has a large computing power and access to a large database.

Embedded machine learning algorithms could be also implemented within the processing unit of the sensor. The computing capabilities may be constrained and the design of the machine learning algorithm is more challenging. First, algorithm complexity, accuracy versus computing capabilities is considered. Secondly, effort to implement and optimize and validate such algorithm is higher. However, an embedded machine learning algorithm has the benefit to provide the only necessary information and enable the management of multiple measurements into embedded systems working in harsh environments.

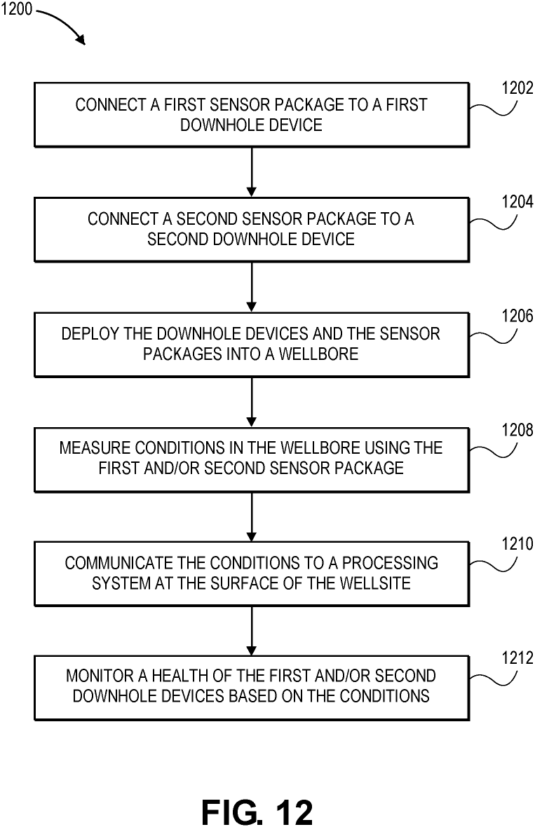

FIG. 12 illustrates a flowchart of a method 1200 for measuring downhole conditions at a wellsite, according to an embodiment. The method 1200 may proceed using one or more embodiments of the sensor package 200 discussed above (or a plurality of such sensor packages 200, as provided in the network 1100), and is thus described herein with reference thereto. Such reference is provided for ease of understanding and convenience, and not by way of limitation; indeed, at least some embodiments of the method 1200 may employ other devices.

The method 1200 may include connecting a (e.g., first) sensor package 200A to a downhole device 1102, as at 1202. The sensor package 200A may be connected to the downhole device 1102 via a PCB 500 that is connected to a chassis 1106, such that a transmissibility of the PCB 500 is approximately 1. Further, the first sensor package 200A may be constructed at least partially from one or more ICs 212 stacked together with one or more transducer chips 216. The first sensor package 200A may be configured for survival and operation in the harsh (high temperature, high pressure, shock, vibration, humidity, etc.) conditions within the well.

The method 1200 may, in some embodiments, including connecting a second sensor package 200B to a second downhole device 1104, as at 1204. The second sensor package 200B may be the same or a similar design as the first sensor package 200A.

The method 1200 may then include deploying the first and second sensor packages 200A, 200B into a wellbore, along with the first and second downhole devices 1102, 1104, as at 1206. The method 1200 may then include measuring a plurality of downhole conditions using multiple different MEMS sensors, for example, provided by each individual one of the first and second sensor packages 200A, 200B, as at 1208.

In some embodiments, the sensor packages 200A, 200B may be configured to process the measurement signals received from the sensors thereof, as at 1206. For example, processors of the sensor packages 200A, 200B may produce data that describes the measurements acquired by the sensors, e.g., to reduce a transmission size relative to the raw signals. In other embodiments, the sensor packages 200A, 200B may simply convert the sensor measurements from analog to digital and store or otherwise prepare the raw measurement data for transmission.

The sensor packages 200A, 200B may then communicate (either the raw or processed data) signals to a central processing device 1110, as at 1210. The central processing device 1110 may monitor a health of the downhole devices 1102, 1104 based on the data signals received from the sensor packages 200A, 200B connected thereto, respectively, as at 1202.

In one or more embodiments, the functions described can be implemented in hardware, software, firmware, or any combination thereof. For a software implementation, the techniques described herein can be implemented with modules (e.g., procedures, functions, subprograms, programs, routines, subroutines, modules, software packages, classes, and so on) that perform the functions described herein. A module can be coupled to another module or a hardware circuit by passing and/or receiving information, data, arguments, parameters, or memory contents. Information, arguments, parameters, data, or the like can be passed, forwarded, or transmitted using any suitable means including memory sharing, message passing, token passing, network transmission, and the like. The software codes can be stored in memory units and executed by processors. The memory unit can be implemented within the processor or external to the processor, in which case it can be communicatively coupled to the processor via various means as is known in the art.

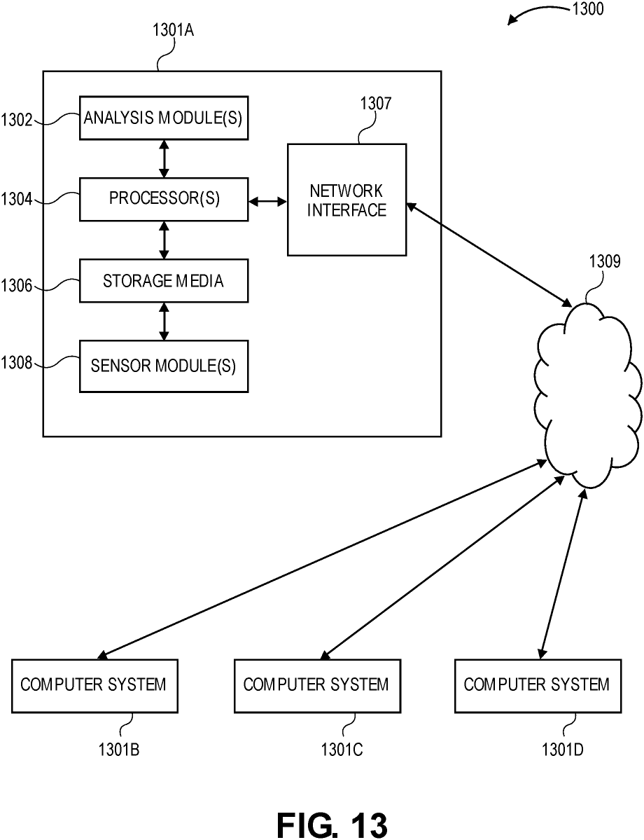

In some embodiments, any of the methods of the present disclosure may be executed by a computing system. FIG. 13 illustrates an example of such a computing system 1300, in accordance with some embodiments. The computing system 1300 may include a computer or computer system 1301A, which may be an individual computer system 1301A or an arrangement of distributed computer systems. The computer system 1301A includes one or more analysis module(s) 1302 configured to perform various tasks according to some embodiments, such as one or more methods disclosed herein. To perform these various tasks, the analysis module 1302 executes independently, or in coordination with, one or more processors 1304, which is (or are) connected to one or more storage media 1306. The processor(s) 1304 is (or are) also connected to a network interface 1307 to allow the computer system 1301A to communicate over a data network 1309 with one or more additional computer systems and/or computing systems, such as 1301B, 1301C, and/or 1301D (note that computer systems 1301B, 1301C and/or 1301D may or may not share the same architecture as computer system 1301A, and may be located in different physical locations, e.g., computer systems 1301A and 1301B may be located in a processing facility, while in communication with one or more computer systems such as 1301C and/or 1301D that are located in one or more data centers, and/or located in varying countries on different continents).

A processor can include a microprocessor, microcontroller, processor module or subsystem, programmable integrated circuit, programmable gate array, or another control or computing device.

The storage media 1306 can be implemented as one or more computer-readable or machine-readable storage media. Note that while in the example embodiment of FIG. 13 storage media 1306 is depicted as within computer system 1301A, in some embodiments, storage media 1306 may be distributed within and/or across multiple internal and/or external enclosures of computing system 1301A and/or additional computing systems. Storage media 1306 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above can be provided on one computer-readable or machine-readable storage medium, or alternatively, can be provided on multiple computer-readable or machine-readable storage media distributed in a large system having possibly plural nodes. Such computer-readable or machine-readable storage medium or media is (are) considered to be part of an article (or article of manufacture). An article or article of manufacture can refer to any manufactured single component or multiple components. The storage medium or media can be located either in the machine running the machine-readable instructions, or located at a remote site from which machine-readable instructions can be downloaded over a network for execution.

In some embodiments, computing system 1300 contains one or more sensing module(s) 1308. In the example of computing system 1300, computer system 1301A includes the sensing module 1308. In some embodiments, a single sensing module may be used to perform some or all aspects of one or more embodiments of the methods. In alternate embodiments, a plurality of sensing modules may be used to perform some or all aspects of methods.

It should be appreciated that computing system 1300 is only one example of a computing system, and that computing system 1300 may have more or fewer components than shown, may combine additional components not depicted in the example embodiment of FIG. 13, and/or computing system 1300 may have a different configuration or arrangement of the components depicted in FIG. 13. The various components shown in FIG. 13 may be implemented in hardware, software, or a combination of both hardware and software, including one or more signal processing and/or application specific integrated circuits.

Further, the steps in the processing methods described herein may be implemented by running one or more functional modules in information processing apparatus such as general-purpose processors or application-specific chips, such as ASICs, FPGAs, PLDs, or other appropriate devices. These modules, combinations of these modules, and/or their combination with general hardware are all included within the scope of protection of the invention.

Geologic interpretations, models and/or other interpretation aids may be refined in an iterative fashion; this concept is applicable to embodiments of the present methods discussed herein. This can include use of feedback loops executed on an algorithmic basis, such as at a computing device (e.g., computing system 1300, FIG. 13), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. Moreover, the order in which the elements of the methods are illustrated and described may be re-arranged, and/or two or more elements may occur simultaneously. The embodiments were chosen and described in order to best explain the principles of the invention and its practical applications, to thereby enable others skilled in the art to best utilize the invention and various embodiments with various modifications as are suited to the particular use contemplated.

What is claimed is:

1. A downhole sensor system, comprising:
a first sensor package, comprising:
a substrate;
an integrated circuit chip mounted to the substrate, the integrated circuit chip including a processor;
a transducer chip mounted to the integrated circuit chip; and
a plurality of sensors configured to measure at least shock, pressure, temperature, and humidity, wherein at least one of the plurality of sensors is mounted to the transducer chip such that a stack is formed at least from the substrate, the integrated circuit, the transducer chip, and the sensor, and wherein the plurality of sensors are in communication with the processor.

2. The downhole sensor system of claim 1, wherein the sensors comprise micro-electromechanical system (MEMS) devices.

3. The downhole sensor system of claim 1, further comprising:
a printed circuit board, the substrate being mounted to the printed circuit board; and
a clamp extending along at least one side of the printed circuit board.

4. The downhole sensor system of claim 3, wherein the substrate, integrated chip, and transducer chip are positioned on the printed circuit board proximal to the clamp, such that a transmissibility of the printed circuit board is approximately 1.

5. The downhole sensor system of claim 3, wherein the substrate is coupled to the printed circuit board using a ball grid array, a pin grid array, a land grid array, or a combination thereof, and wherein a connection is not made between the substrate and the printed circuit board at least at a corner of the substrate.

6. The downhole sensor system of claim 1, wherein the substrate is constructed of resin filled with ceramic, glass, or both.

7. The downhole sensor system of claim 1, wherein the substrate comprises a metallization that is configured for use with soldering and wire bonding.

8. The downhole sensor system of claim 1, wherein the substrate comprises a metallization that is configured for flip-chip connection.

9. The downhole sensor system of claim 1, wherein the plurality of sensors further comprise at least one of a sensor configured to measure a presence of volatile organic compounds, an accelerometer, a gyroscope, or a magnetometer.

10. The downhole sensor system of claim 1, wherein the plurality of sensors are configured to measure a temperature range of -55 C to 200 C, relatively humidity of at least 10%, and shock of up to 10,000 g.

11. The downhole sensor system of claim 10, wherein the substrate is at most 10 mm by 10 mm, so as to have a coefficient of thermal expansion that avoids decoupling from the integrated circuit chip in the temperature range.

12. The downhole sensor system of claim 1, further comprising:
a plurality of sensor packages including the first sensor package and each configured to measure at least temperature, humidity, shock, and pressure, the plurality of sensors being distributed at different locations along a drilling apparatus.

13. A method for measuring downhole conditions, comprising:
connecting a first sensor package to a first downhole device, the first sensor package comprising:
a substrate;
an integrated circuit chip mounted to the substrate, the integrated circuit chip including a processor;
a transducer chip mounted to the integrated circuit chip; and
a plurality of sensors configured to measure at least shock, pressure, temperature, and humidity, wherein at least one of the plurality of sensors is mounted to the transducer chip such that a stack is formed at least from the substrate, the integrated circuit, the transducer chip, and the sensor, and wherein the plurality of sensors are in communication with the processor;
measuring conditions using the first sensor package; and
communicating the conditions from the first sensor package to a processing system using the processor of the first sensor package.

14. The method of claim 13, further comprising:
connecting a second sensor package to a second downhole device;
measuring the conditions using the second sensor package; and
communicating the conditions from the second sensor package to the processing system using a processor of the second sensor package.

15. The method of claim 13, wherein the sensors comprise micro-electromechanical system (MEMS) devices.

16. The method of claim 13, wherein the first sensor package further comprises a printed circuit board, the substrate being mounted to the printed circuit board, and a clamp extending along at least one side of the printed circuit board, and wherein connecting the first sensor package to the first downhole device comprises clamping the printed circuit board to a chassis.

17. The method of claim 16, wherein the substrate, integrated chip, and transducer chip are positioned on the printed circuit board proximal to the clamp, such that a transmissibility of the printed circuit board is approximately 1.

18. The method of claim 13, wherein measuring the conditions comprises measuring a presence of volatile organic compounds or an internal condition of the first downhole device.

19. The method of claim 13, wherein measuring the conditions comprises measuring a temperature in a range of -55C to 200C, measuring a relatively humidity of at least 5%, and measuring a shock of at least 1000 g and up to 10,000 g.

20. A sensor package, comprising:
a substrate;
an integrated circuit chip mounted to the substrate, the integrated circuit chip including a processor;
a transducer chip mounted to the integrated circuit chip; and
a plurality of sensors configured to measure at least shock, pressure, temperature, and humidity,
wherein at least one of the plurality of sensors is mounted to the transducer chip such that a stack is formed at least from the substrate, the integrated circuit, the transducer chip, and the sensor,
wherein the plurality of sensors are in communication with the processor,
wherein the sensors comprise micro-electromechanical system (MEMS) devices, and
wherein the plurality of sensors are configured to measure a temperature range of -55 C to 200 C, relatively humidity of at least 10%, and shock of up to 10,000 g.
